(19) United States
(12) Patent Application Publication
(10) Pub. No.: US 2018/0309043 A1
(43) Pub. Date: Oct. 25, 2018

(54) TRANSPARENT ULTRASONIC TRANSDUCER FABRICATION METHOD AND DEVICE

(71) Applicant: Innovasonic, Inc., Dublin, CA (US)

(72) Inventors: Boris Kobrin, Dublin, CA (US); Joseph Bernhardt Geddes, III, Berkeley, CA (US)

(73) Assignee: Innovasonic, Inc., Dublin, CA (US)

(21) Appl. No.: 15/645,991

(22) Filed: Jul. 10, 2017

Related U.S. Application Data
(63) Continuation of application No. PCT/US2016/021836, filed on Mar. 10, 2016.
Application No. PCT/US2016/021836 is a continuation of application No. PCT/US2016/015448, filed on Jan. 28, 2016.
(60) Provisional application No. 62/117,906, filed on Mar. 16, 2015.

(51) Int. Cl. H01L 41/08; B06B 1/06; H01L 41/047; H01L 41/29; H01L 41/331

(52) U.S. Cl. CPC H01L 41/081; B06B 1/0629; H01L 41/331; H01L 41/29; H01L 41/047

(57) ABSTRACT

A transparent ultrasonic transducer device includes a transparent substrate, one or more transparent conductors, and a patterned piezoelectric material layer or, alternatively, a transparent piezoelectric film and one or more transparent conductors, wherein the piezoelectric layer is formed on essentially an entire transparent substrate surface, including a central area of the transparent substrate.

### 1. CLAIM OF PRIORITY

This Application claims the priority benefit of International Patent Application Number PCT/US2016/021836, filed Mar. 10, 2016, the entire disclosures of which are incorporated herein by reference.

International Patent Application Number PCT/US2016/021836 claims the priority benefit of International Patent Application Number PCT/US2016/015448, filed Jan. 28, 2016, the entire contents of which are incorporated herein by reference. International Patent Application Number PCT/US2016/021836 also claims the priority benefit of U.S. Provisional Patent Application No. 62/117,906 filed Mar. 16, 2015, the entire disclosures of which are incorporated herein by reference.

### 2. FIELD OF THE DISCLOSURE

The present disclosure relates to ultrasonic transducers and more particularly to transparent ultrasonic transducers.

### 3. BACKGROUND

Ultrasonic transducers are widely used to clean surfaces from contamination. Moreover such transducers would be very useful for cleaning transparent surfaces like vehicle windshields, windows and sunroofs, and of course building windows. The requirements of any window device include high transparency and unobstructed view.

The concept of ultrasonic wiperless windshield cleaners can be traced back to the early 1960s. U.S. Pat. No. 3,171,683 (filed in 1963) covers Arthur Ludwig's concept for a “Windshield assembly for motor vehicles and the like.”

In essence, the transducers shake the glass, so that rain, snow, mud, etc. do not stick. However, there appears to be no evidence that the concept was ever demonstrated.

The next significant advance in ultrasonic windshield cleaners was made by Kenro Motoda. His approach, as recorded in U.S. Pat. No. 4,768,256 (filed in 1986), looks rather like Ludwig's, in that there are a set of ultrasonic transducers fixed onto the windshield.

However, his transducers are actually launchers for surface acoustic waves. Unlike conventional vibrations, which generally produce a pattern of standing (stationary) waves on the surface of the glass, surface acoustic waves move the surface of the glass in an elliptical pattern that propagates across the glass, hopefully carrying along with it water, dirt, and other muck obscuring the driver's view. While the progressive motion of the surface acoustic waves should be more effective than the simple shaking of the Ludwig design, it appears that Motoda's design was never produced.

A number of modifications of Motoda's basic design were patented over the years, including one that involved the piezoelectric polymer polyvinylidine fluoride being sandwiched between transparent conducting electrodes to generate the surface acoustic waves, (Broussoux et al, U.S. Pat. No. 5,172,024 (1990)); as well as applications to cleaning semiconductor wafers (Akatsu et al., U.S. Pat. No. 6,021,789 (1998)), and for shaking dust from camera optics (Urakami et al., U.S. Pat. No. 8,063,536 (2009).

The most recent patent activity in this field is described in International Patent Application Publication WO2012095643, filed in 2011 by a small UK engineering firm, Echovista Systems Ltd. While the basic technique is still that of Motoda, the Echovista publication has expanded the possible modes of usage to include ultrasonic vaporization of precipitation from the windshield, the use of other vibrational modes which may be more effective in removing precipitation, using the heating of the windshield caused by the ultrasonic vibration to melt ice and snow and de-fog the windshield, and the use of a windshield washing liquid nozzle, having an effect similar to plunging the windshield into an ultrasonic cleaner. Echovista also appears to have done significant testing on its ultrasonic washer, identifying maximum effectiveness is obtained with an ultrasonic frequency of about 2 MHz, corresponding to an ultrasonic wavelength of about 2.5 mm (0.1 in).

Obviously, all prior art had to position their “macro” ultrasonic transducers 1, 2, 3, 4, 5, 6, 7, 8, on the periphery 9 of the window/windshield 10 to be cleaned (not to obstruct a view) which is shown on FIG. 1. In order to clean a specific place on the large windshield an ultrasonic energy should travel from the edge to the point of application, which causes significant loos of energy and as a result requires larger US power.

Similar ultrasonic devices could be used to clean solar panels and architectural windows from contamination. Prior art (Vasiliev, 2013) used macro-ultrasonic device located outside of the working area of the solar panel. Ultrasonic cleaning is a very important and economically efficient solution, since allows to significantly boost efficiency of energy generation, avoid using manual labor or expensive robotics.

Efficiency of cleaning could be much higher and power requirements much lower if US transducers could be positioned in a very close proximity/or even right at the point of contamination within a viewing/exposure area of a windshield, window, sunroof or solar panel. But for this to happen such transducer must be not only very transparent, but in case of a windshield, absolutely invisible to the human eye from a short distance of viewing within a vehicle.

Another wide-spread ultrasonic transducer's application is in sensing. Again, most devices have used macro-transducers and could not be implemented on optical devices, displays, windows and windshields. For example, gesture recognition system of Boser (US20140253435) uses an array of microelectromechanical (MEMS) ultrasonic transducers fabricated on Si substrate for emitting acoustic signal and sensing it after reflecting from a moving object. Yet another example is the application of Lee (US20130127783), where ultrasonic transducers (emitters and receivers) located on the periphery of display window. Obviously, such non-transparent obstructive devices cannot be integrated in a transparent object like window or display. Providing such an array is made transparent it could be integrated on the display window to provide non-optical (without cameras) gesture recognition or 3D image caption, which could use 20× less power than camera-based gesture recognition systems, and be more private.

It is within this context that aspects of the present disclosure arise.

### 4. BRIEF DESCRIPTION OF THE DRAWINGS

Various aspects of the present disclosure will become apparent upon reading the following detailed description and upon reference to the accompanying drawings in which:

FIG. 1 is a schematic diagram illustrating an example of a prior art ultrasonic windshield cleaning system in which transducers are attached to glass substrates on the periphery.

FIGS. 2A-2C are schematic diagrams illustrating examples of transparent microstructured piezoelectric transducers in accordance with various aspects of the present disclosure.

FIG. 3 is a cross-sectional schematic diagram of a thin film stack structure for a transparent microstructured piezoelectric transducer in accordance with certain aspects of the present disclosure.

FIG. 4A is a cross-sectional schematic diagram illustrating a patterned thin film stack for a transparent microstructured piezoelectric transducer after a lift-off process according to an aspect of the present disclosure.

FIG. 4B is a cross-sectional schematic diagram illustrating an alternative configuration for a patterned thin film stack for a transparent microstructured piezoelectric transducer after a lift-off process according to an aspect of the present disclosure.

FIG. 5 is a plan view schematic diagram illustrating a transparent metal electrode having interdigitated-lines fabricated on a transparent piezoelectric film (according to an aspect of the present disclosure

FIG. 6 is a schematic diagram depicting design for a transparent microstructured piezoelectric transducer device having an array of individually addressable areas.

FIG. 7 is a schematic diagram showing an example of a design of a transparent ultrasonic rangefinder having array of ultrasonic emitters and an array of ultrasonic sensors fabricated from transparent microstructured piezoelectric transducers in accordance with aspects of the present disclosure.

FIG. 8 is a schematic diagram showing an example of a system 80 having two or more arrays of transparent transducers fabricated on a transparent substrate and coupled to a controller.

FIG. 9 is a schematic diagram showing an example of an implementation in which transparent transducers are used for wireless charging across a transparent substrate.

FIG. 10 illustrates an example of a display having integrated transparent ultrasonic transducers according to an alternative aspect of the present disclosure.

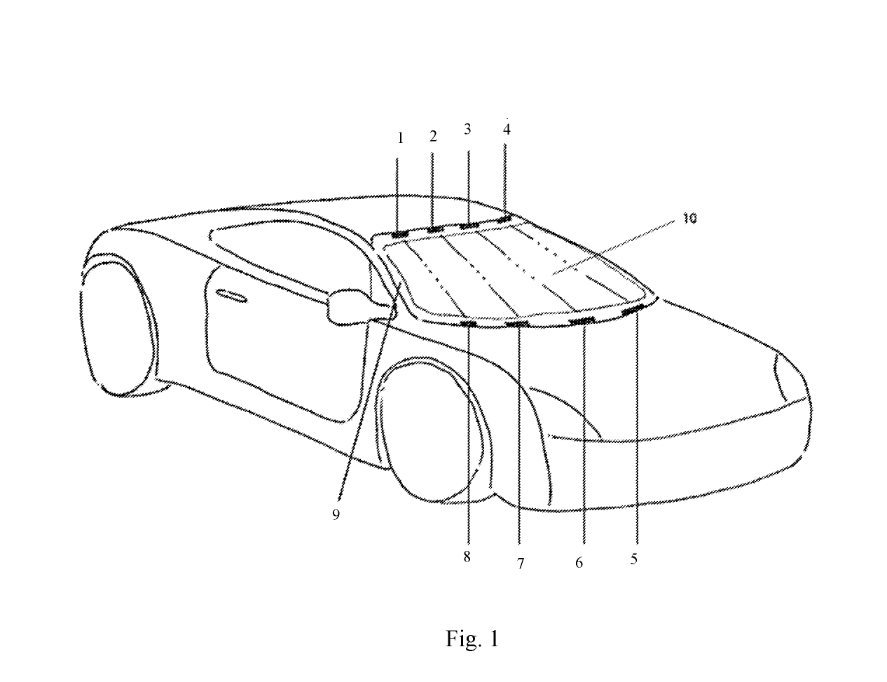

### 5. DETAILED DESCRIPTION

Although the following detailed description contains many specific details for the purposes of illustration, anyone of ordinary skill in the art will appreciate that many variations and alterations to the following details are within the scope of the invention. Accordingly, the aspects of the disclosure described below are set forth without any loss of generality to, and without imposing limitations upon, the claimed invention.

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” “first,” “second,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

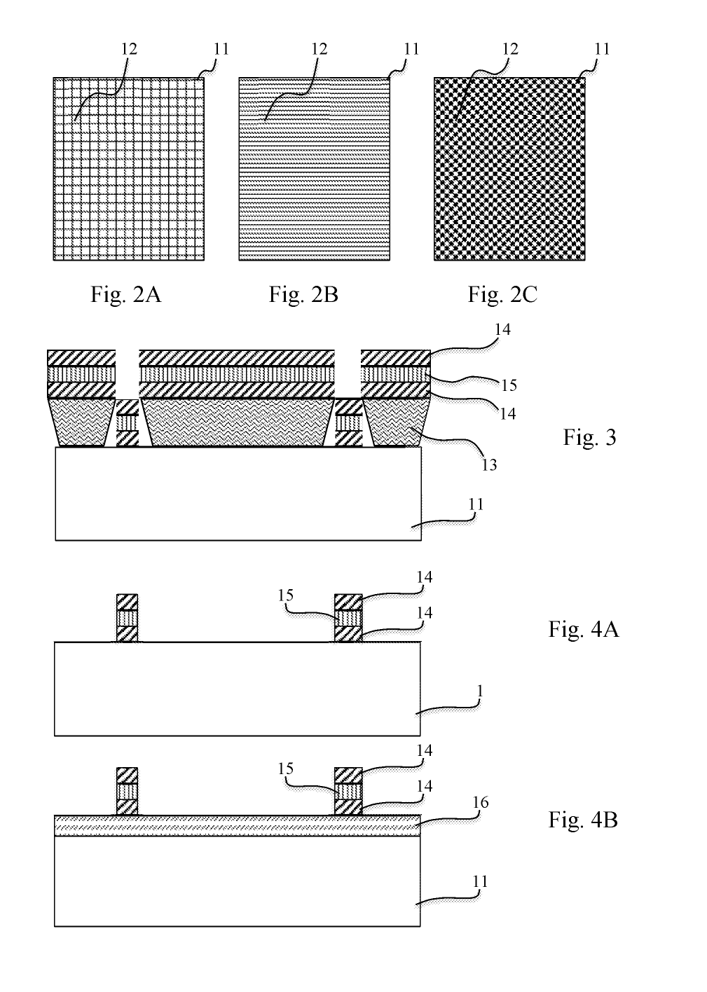

Aspects of the present disclosure include transparent ultrasonic devices and methods of manufacturing. Such transducer devices may include a micro- or nano-structured mesh (12) as in FIG. 2A or a grating (12′), as in FIG. 2B, or an array (12″), as in FIG. 2C on the surface of a substrate (11), for example glass or polymer film. The criteria of transparency for such transducers could be met by optimizing a ratio of microstructure to an open area of the substrate. The criteria of visibility (unobstructed view) can be met by optimizing the feature size of the structure to be below recognition of a human eye at the required distances. That minimum feature size is usually less than 5 micron, though for the most demanding applications and good human vision, it could be less than 2.5 micron.

A micro- or nano-structured ultrasonic transducer could be made of a piezoelectric material sandwiched between 2 electrodes, e.g., as shown in FIG. 3. Moreover, both, a piezoelectric thin film (15) and electrodes (14), could be patterned on the substrate surface to yield a very transparent and invisible-to-the-eye device. In an alternative implementation, one or both electrodes could be deposited as a continuous layer of transparent conductive material, and only piezoelectric material would be patterned. Such transparent conduct material could be, e.g., Indium-Tin Oxide (ITO) or another transparent conductive oxide (TCO), or transparent organic conductors, or graphene, or silver nanowires or nanoparticles. Another embodiment could use microelectromechanical systems (MEMS) technology for manufacturing an invisible-to-the-eye array of piezoelectric transducers on a transparent substrate.

For applications involving surface cleaning of, e.g., windshields, windows, displays and solar panels, ultrasonic transducers could be used in tandem with surface modification techniques, such as making substrate surface hydrophobic, superhydrophobic, or superhydropholic, or photoactive (for example, containing a titanium dioxide (TiO₂) composition).

Aspects of the present disclosure include, but are not limited to, the following embodiments.

### Embodiment-I

The following thin film stack can be deposited on a glass or plastic film surface in the viewing area of the device (for example, windshield): thin metal film (for example, silver), piezoelectric material (for example, lead zirconate titanate (PZT), lead lanthanum zirconate titanate (PLZT), barium titanate, ammonium dihydrogen phosphate (ADP), etc.), and thin metal film again (for example, silver). Those materials could be deposited from the vapor phase using sputtering or evaporation, or in the liquid form of suspension particles (nanoink) or in the Sol-Gel form by spinning, dip-coating, slot-die coating, xerography, gravure, screen printing, inkjet printing, microcontact printing, aerosol deposition or others).

The substrate could be additionally pre-patterned with hydrophobic (superhydrophobic) and hydrophilic (superhydrophilic) areas to enhance resolution or control adhesion or structure of deposited materials.

In order to reduce visibility of piezoelectric or conductive features to the human eye, e.g., from a distance of a couple of feet (for a car windshield, for example) the pattern preferably has features with a linewidth of less than 5 micron, more preferably less than 3 micron linewidth, and ideally less than 2 micron linewidth.

The deposition may be done according to any desired pattern (for example, a one-dimensional grating of straight or curved lines or a two-dimensional mesh or an array of small islands, etc.).

The pattern could be uniform/continuous over the surface or divided to multiple areas individually addressable by application of ultrasonic power in order to be able to forward power only to the area where cleaning is necessary.

### Embodiment-II

A substrate, for example glass, is coated with the following thin film stack using, for example, sputtering technique: a thin metal film (for example, silver), a layer of piezoelectric material (for example, PZT), and another thin metal film (for example, silver). Then this stack is then patterned using a suitable patterning technique, for example, laser ablation. Alternatively one can use any of the following patterning techniques followed by material etching: electron-beam lithography, ultraviolet (UV) lithography, nanoimprint lithography, optical lithography, interference lithography, laser scanning lithography, self-assembly, etc. The type of lithography may be chose based on considerations of cost, scalability, and resolution of patterning required for achieving a specific optical, mechanical and cosmetic performance of the device being fabricated.

### Embodiment-III

As shown in FIG. 3, a substrate (11) is coated with a photosensitive layer (13),—e.g., a photoresist (or multiple layers of photoresist). Then the photosensitive layer (13) is patterned using optical lithography which assures reentrant profile of the patterned photoresist features. The following stack is then deposited on the patterned photosensitive layer (13): a first thin metal film (14), for example, silver, a piezoelectric material (15), for example, PZT, and a second thin metal film (14), for example, silver. Finally a lift-off process is done by dissolving the photosensitive layer (13) to yield a microstructured metal stack on the substrate surface, as shown in FIG. 4A.

The substrate (11) may be any suitable transparent material, e.g., glass, plastic, etc. The PZT layer stack (piezoelectric material 15 sandwiched between metal films 14) may be formed directly on a surface of the substrate (11). In alternative implementations, the PZT layer stack may be formed on a layer of soft material (16) between the PZT layer stack and the substrate (11), as shown in FIG. 4B to increase ultrasonic energy output to the air. By way of example, and not by way of limitation, the soft material (16) may be polymer, for example, silicone.

### Embodiment-IV

In this embodiment, a substrate is coated with a polymer layer, which is then patterned, e.g., using a nanoimprint method. Then, the following materials stack is deposited in protrusions formed as a result of nanoimprint patterning: a metal layer, a piezoelectric material layer, and finally another metal layer. Alternatively, just metal and piezo-electric material if an interdigitated design is used.

### Embodiment-V

In this embodiment, a substrate with conductive layer is patterned with superhydrophobic material (e.g., a self-assembled monolayer) using lithography and lift-off, laser ablation or direct microcontact printing. Then piezoelectric material (PZT) is deposited and annealed; PZT on top of superhydrophobic material can't be crystalized and remains amorphous, thus could be removed during lift-off process.

### Embodiment-VI

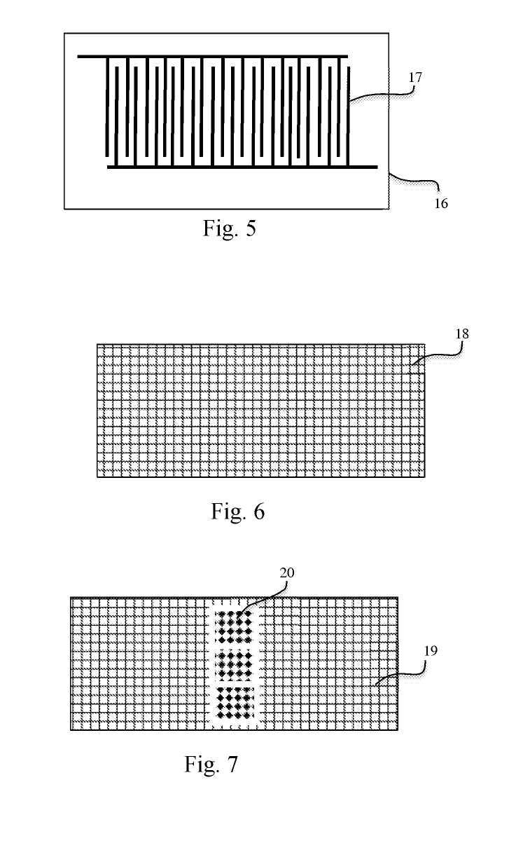

As shown in FIG. 5, a transparent piezoelectric film (16) is coated with photosensitive layer, such as a—photoresist (or multiple layers of photoresist). The photosensitive layer is then patterned using an optical lithography that assures reentrant profile of the patterned photoresist features. In this case, the pattern includes interdigitated lines or trenches. The patterned photoresist is then coated with a metal or other conductive material. Finally a lift-off process is done by dissolving photosensitive layer (or layers) to yield a transparent array of electrically isolated interdigitated metal electrodes (17) on the surface of a transparent piezoelectric film.

### Embodiment-VII

In this embodiment, a substrate is coated with a photosensitive layer, e.g., a photoresist (or multiple layers of photoresist). Then the photosensitive layer is patterned using an optical lithography that assures a reentrant profile of the patterned photoresist features. The pattern includes interdigitated lines or trenches. The substrate is then coated with metal material. Then a lift-off process is done by dissolving photosensitive layer (or layers) to yield a microstructured metal stack on the substrate surface. Finally, a transparent piezoelectric film, for example polyvinylidine fluoride—PVDF films (Kynar® Film & Solef® Film or others), is laminated to the substrate over the patterned electrodes on the substrate surface with an impedance matching material sandwiched between the piezoelectric film and the electrode pattern.

### Embodiment-VIII

As shown in FIG. 6, an entire substrate, e.g., a—windshield or window, can be divided on multiple areas with an array of individually powered ultrasonic transducers 8 to save energy for forwarding ultrasonic power only to the area where contamination should be removed. Also, the individually addressable ultrasonic transducers or arrays of transducers allow creating an ultrasonic wave to dislodge and move contamination or water droplets on the surface in required direction.

### Embodiment-IX

As seen in FIG. 7, two or more arrays of transparent transducers (20) may be fabricated on a transparent substrate (19). One array is designed to emit acoustic signals, and another array is designed to sense acoustic signals reflected from an object positioned in front of the device. By coupling the transducer arrays to appropriate electronics, this device can be configured to capture a three-dimensional image from emitted acoustic energy that is reflected from a static or moving object (e.g., a face, fingerprint, part, etc.) and detected. A device so configured could provide 3D image capture or gesture recognition functionality. By using acoustic transducers according to aspects the present disclosure described herein, this device can be made completely invisible to the human eye and can be fabricated on a transparent object, such as a display, window, mirror or glass lens.

### Embodiment-X

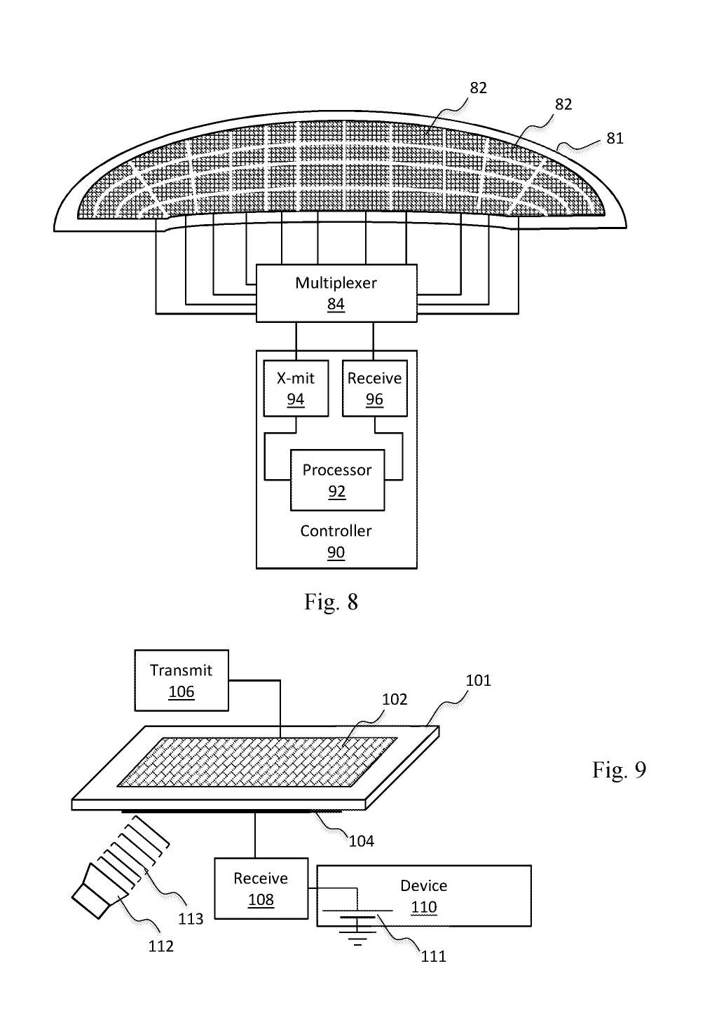

There are a number of ways to implement Embodiments VIII and IX. FIG. 8 illustrates a system 80 having two or more arrays of transparent transducers 82 fabricated on a transparent substrate 81 and coupled to a controller 90. The controller may include a processor 92 coupled to a transmit circuit 94 and a receive circuit 96. In the illustrated example, the arrays of transparent transducers 82 are operatively coupled to the controller 90 via a multiplexer 84. The multiplexer allows the transmit circuit 94 or the receive circuit 96 to be selectively coupled to individual arrays on the substrate 81. The processor 92 may be a programmable microprocessor, a microcontroller, an application specific integrated circuit (ASIC), field programmable gate array (FPGA), or other suitable device. It is noted that in some implementations, the multiplexer 84, processor 92, transmit circuit 94, and receive circuit 96 may be implemented in a common integrated circuit, such as a system on chip (SOC).

The transmit circuit 94 provides drive signals that drive the transducers 82 in response to drive instructions from the processor 92. Providing the drive instructions may involve interpretation of digital drive instructions and generation of corresponding analog output signals having sufficient amplitude to generate a desired ultrasound signal with a particular transducer. The drive signals may include switching signals that direct the multiplexer 84 to selectively couple the analog output signals to the particular transducer. By way of example and not by way of limitation, the processor 92 may send drive instructions to the transmit circuit 94 that direct the transmit circuit to couple drive signals to selected arrays in a sequence that sends transverse waves of ultrasound across the substrate from one end to the other.

The receive circuit receives 96 input signals from the transducers 82 and converts the received signals into a suitable form for signal processing by the processor. Conversion of the received signals may involve amplification of the received signals and conversion of the resulting amplified received signals from analog to digital form. The processor may be programmed or otherwise configured to perform digital signal processing on the resulting digital signals. Such digital signal processing may include time of flight analysis to determine a distance d to an object. Such time of flight analysis may involve determining an elapsed time At between the transmitting of acoustic pulses with one or more of the transducers 82 and detecting an echo of such pulses from the object with the same or different transducers 82. The processor 92 can calculate the distance d from the equation d=cΔt, where c is a known or estimated speed of sound.

Aspects of the present disclosure allow for ultrasonic transducers to be integrated directly into transparent structures such as vehicle windshields, architectural glass, solar panels, and video displays in a manner that is invisible to the human eye. Integrating ultrasonic transducers into such structures opens up possibilities for implementing self-cleaning, acoustic range finding, gesture recognition and other capabilities in transparent structures.

Applications of transparent ultrasonic transducers include many other applications in addition to those described above. Another possible application of transparent ultrasonic transducer array is glass/window/display-integrated speaker. This may be implemented, e.g., by modifying the system shown in FIG. 8 so that the processor 92 drives the transducers 82 as transparent acoustic speakers. In such applications, the transparent substrate 81 could be building or transportation windows, or product packaging windows, or lighting fixtures, or other transparent objects with audio capabilities. The processor 92 may also provide the transparent speakers with noise-cancelling capabilities as well.

Another potential application is distance sensing or proximity tooling for medical testing or operations, where a microscope or camera lens or other optics must be in a very close proximity to the tissue, but not touching it. For example, intraocular pressure measurements. A transparent range-finder integrated in an optical fiber or optical lens could be very useful in such applications.

Yet another application depicted in FIG. 9, involves wireless charging of devices through windows, displays and other transparent objects. For example, a first transparent ultrasonic transducer (or array of such transducers) 102 formed or attached on one side of the transparent object 101 that is driven by a transmitter circuit 106 may transmit acoustic energy that is received by a second transparent ultrasonic transducer (or second array of such transducers) 104 formed or attached on an opposite side of the transparent object. In alternative implementations the two transducers/arrays may be formed on the same side of the object 101. The first transducer or array can convert electrical energy into transmitted acoustic energy and the second transducer or array converts the received acoustic energy into electrical energy, which may be coupled to by a receiver 108 to charge a device 110, e.g., to power the device or charge the device's battery 111.

A variation on the application illustrated in FIG. 9 is harvesting energy (mechanical or acoustical) by windows, displays and other transparent objects. In such applications, one or more transparent acoustic transducers formed on one or more sides of a transparent object 101 can convert acoustic energy 113 received from an external source 112 to electrical energy, which may be stored, e.g., in a rechargeable battery 111 or utilized to power a device 110. In yet another variation, the external source of acoustic energy may be a dedicated transmitter configured to detect the one or more transparent acoustic transducers and direct a focused beam of ultrasonic acoustic energy to the transducers.

### Additional Embodiments

Aspects of the present disclosure are not limited to the above embodiments. Numerous other embodiments are within the scope of the present disclosure.

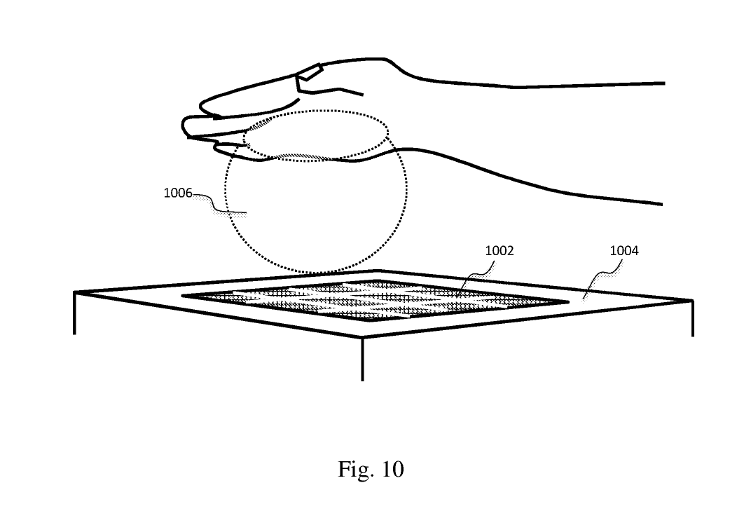

By way of example, and not by way of limitation, transparent ultrasonic transducers may be integrated into a display, such as a flat screen television, computer monitor, smart phone display or tablet computer display. For example, as seen in FIG. 10, an array of transparent ultrasonic transducers 1002 may be integrated into a display 1004 to provide a user with the experience of interacting with haptic touchable 3D shapes 1006. The transducers 1002 may be driven by a controller (not shown), which may include a processor coupled to a transmit circuit and a receive circuit and a multiplexer, e.g., as discussed above with respect to FIG. 8. The volume of the shapes may be defined in software executed by the processor and an object (e.g., a user's hand) may be tracked ultrasonically via acoustic pulses transmitted and received by the transducers in the array. When the location and/or movement of the object is in a predetermined relationship with respect to the software-defined volume, the software may modify the shape, location, orientation, or movement of an object in an image presented on the display 1004 in accordance with the determined location and/or movement of the user's hand and the predetermined relationship.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A transparent ultrasonic transducer device, comprising:
a transparent substrate;
one or more transparent conductors; and
a patterned piezoelectric material layer.

2. The device of claim 1 wherein the piezoelectric layer is formed on essentially an entire transparent substrate surface, including a central area of the transparent substrate.

3. The device of claim 1 wherein the patterned piezoelectric has features characterized by a linewidth less than 10 microns.

4. The device of claim 1 wherein the patterned piezoelectric has features characterized by a linewidth less than 2.5 microns.

5. The device of claim 1 wherein the transparent conductors include TCO, graphene, organic conductor, metal nanowires, or metal nanoparticles.

6. The device of claim 1 wherein the transparent conductors include a metal mesh or grating containing metal lines characterized by a linewidth less than 10 microns.

7. The device of claim 1 wherein the piezoelectric layer is sandwiched between two conductive layers, wherein one of the two conductive layers is attached to the transparent substrate.

8. The device of claim 1 wherein the piezoelectric layer is in contact with only one conductive layer on one side.

9. The device of claim 8 wherein the patterned piezoelectric material includes an array of interdigitated lines.

10. The device of claim 1 wherein the patterned piezoelectric material includes an array of individually-addressable piezoelectric transducers.

11. The device of claim 1 wherein the patterned piezoelectric material includes two or more arrays of piezoelectric transducers, include an array of acoustic emitters, and an array of acoustic sensors.

12. The device of claim 1, wherein the patterned piezoelectric material includes a transducer array configured to emit and receive ultrasonic energy.

13. The device of claim 1, wherein the patterned piezoelectric material includes an array of piezoelectric transducers, and circuitry coupled to the array of piezoelectric transducers to emit and configured to transmit and receive ultrasonic energy via the array of piezoelectric transducers in a time-multiplexing regime.

14. A method of fabrication a transparent ultrasonic transducer, comprised of forming an array of transparent piezoelectric devices across essentially an entire substrate, including a central portion of the substrate, and, wherein the piezoelectric devices having elements with a linewidth less than 5 micron.

15. A method according to claim 14 wherein the piezoelectric devices have elements with a linewidth less than 10 micron.

16. A method according to claim 14 wherein the piezoelectric devices have elements with a linewidth less than 2.5 micron.

17. A method according to claim 14 wherein forming the array of transparent piezoelectric devices includes depositing the array of transparent piezoelectric devices by inkjet or microcontact printing.

18. A method according to claim 14 wherein depositing the array of transparent piezoelectric devices is done on pre-patterned substrate with hydrophobic or superhydrophobic and hydrophilic or superhydrophilic areas.

19. A method according to claim 14 wherein forming the array of transparent piezoelectric devices includes nanoimprint lithography with subsequent deposition of conductive and piezoelectric layers in a stack and removal of deposited materials from selected portions of a top surface of the stack.

20. A method according to claim 14 wherein forming the array of transparent piezoelectric devices includes optical or electron beam lithography with subsequent development of a pattern in a layer of a photoresist, deposition of a stack of conductive and piezoelectric layers, and lift-off of selected portions of the photoresist.

21. A method according to claim 14 wherein forming the array of transparent piezoelectric devices includes optical or electron beam lithography with subsequent development of a pattern in a layer of a Sol-Gel piezoelectric photoresist

22. A method according to 14 wherein forming the array of transparent piezoelectric devices includes a process of micro- or nano-pattern transfer from a sacrificial or intermediary substrate

23. A method of fabricating a transparent ultrasonic transducer, comprising attaching a piezoelectric film to one or two patterned transparent conductive films.

24. A method according to claim 23 wherein the one or two conductive films have elements with a linewidth less than 10 micron.

25. A method according to claim 23 wherein such conductive films having elements with a linewidth less than 2.5 micron.

26. A method according to claim 23 wherein the piezoelectric film is sandwiched between two transparent conductive films

27. A method according to claim 23 wherein an impedance matching material is positioned between each of the one or two transparent conductive films and the piezoelectric film.

28. A method according to claim 23, wherein the piezoelectric film is in contact with only one conductive film on one side.

29. The method of claim 23, wherein the one or two patterned transparent conductive films include a metal mesh pattern in the form of an array of interdigitated lines.

30. The method of claim 23, wherein the one or two patterned transparent conductive films include an array of individually-addressable piezoelectric transducers

31. The method of claim 23, further comprising laminating the film stack to a glass substrate.

32. The method of claim 23, wherein forming the array of transparent piezoelectric devices includes forming the array of transparent devices on a layer of soft material disposed on the transparent substrate.
